(19) United States
(12) Patent Application Publication
(10) Pub. No.: US 2009/0325380 A1
(43) Pub. Date: Dec. 31, 2009

(54) METHOD FOR FORMING ELECTRODE ON SEMICONDUCTOR WAFER

(75) Inventor: Kazuma Sekiya, Ota-Ku (JP)

Correspondence Address: GREER, BURNS & CRAIN, 300 S WACKER DR, 25TH FLOOR, CHICAGO, IL, 60606, US

(73) Assignee: DISCO CORPORATION, Tokyo (JP)

(21) Appl. No.: 12/476,347

(22) Filed: Jun. 2, 2009

(30) Foreign Application Priority Data
Jun. 27, 2008 (JP) 2008-168682

(51) Int. Cl. H01L 21/283

(52) U.S. Cl. 438/674; 257/E21.159

(57) ABSTRACT

In accordance with an embodiment of the present invention, there is provided a method for forming an electrode of a semiconductor wafer. The method includes a masking step of applying a mask having apertures formed in areas corresponding to an electrode area of each device, on the back surface of a semiconductor substrate, and an electrode forming step of depositing, by sputtering, gold on the back surface of the semiconductor substrate for which the masking step has been carried out to thereby form the electrode in the electrode area of each device, on the back surface of the semiconductor substrate. The method further includes a mask separating step of separating the mask applied on the back surface of the semiconductor substrate for which the electrode forming step has been carried out, and a gold collecting step of collecting gold deposited on the mask separated in the mask separating step.

### BACKGROUND OF THE INVENTION

1. Field of the Invention

The present invention relates to a method for forming an electrode on a back surface of a semiconductor wafer having devices in areas defined by plural streets formed in a lattice manner on the front surface of the semiconductor wafer.

2. Description of the Related Art

In a semiconductor device manufacturing step, plural areas are defined by lines along which substrate dividing is to be carried out, called streets, disposed in a lattice manner on the front surface of a semiconductor substrate having a substantially circular disk shape. In the defined areas, devices such as IC, LSI, and IGBT (insulated gate bipolar transistor) are formed. A metal layer to serve as electrodes is deposited on the back surfaces of the individual semiconductor devices such as insulated gate bipolar transistors. A semiconductor wafer obtained by forming insulated gate bipolar transistors or the like on the front surface of the semiconductor substrate is cut along the streets and divided into the individual devices after the metal layer is deposited on the back surface of the semiconductor substrate (refer to e.g. Japanese Patent Laid-Open No. Hei 10-92778).

The metal layer that is deposited on the back surface of the semiconductor substrate and is to serve as the electrodes is formed of gold (Au). It is uneconomical to form the layer composed of gold (Au), which is expensive, also on the area other than the electrode areas of the devices, on the back surface of the semiconductor substrate.

### SUMMARY OF THE INVENTION

An object of the present invention is to provide a method for forming an electrode on a back surface of a semiconductor wafer in which expensive gold (Au) can be used economically.

In accordance with an aspect of the present invention, there is provided a method for forming an electrode on a back surface of a semiconductor substrate of a semiconductor wafer having a plurality of devices formed in areas defined by a plurality of streets formed in a lattice manner on a front surface of the semiconductor substrate, the method comprising: a masking step of applying a mask having a plurality of apertures formed in areas corresponding to each electrode area of the each device, on the back surface of the semiconductor substrate; an electrode forming step of depositing, by sputtering, gold on the back surface of the semiconductor substrate for which the masking step has been carried out to thereby form the electrode in the electrode area of the each device, on the back surface of the semiconductor substrate; a mask separating step of separating the mask applied on the back surface of the semiconductor substrate for which the electrode forming step has been carried out; and a gold collecting step of collecting gold deposited on the mask separated in the mask separating step.

In the method of the present invention, the mask having the apertures formed in the areas corresponding to the electrode area of the each device is applied on the back surface of the semiconductor substrate. Furthermore, gold is deposited by sputtering on the back surface of the semiconductor substrate to thereby form the electrodes in the electrode areas of the devices. Therefore, the minimum necessary amount of gold is deposited on the semiconductor substrate. In addition, the gold deposited on the surface of the mask by sputtering is collected, and thus the gold, which is expensive, can be reused.

The above and other objects, features and advantages of the present invention and the manner of realizing them will become more apparent, and the invention itself will best be understood from a study of the following description and appended claims with reference to the attached drawings showing some preferred embodiments of the invention.

### BRIEF DESCRIPTION OF THE DRAWINGS

FIG. 1 is a perspective view of a semiconductor wafer to be processed by a method for forming an electrode of a semiconductor device in accordance with an embodiment of the present invention;

FIG. 2 is a perspective view showing a state in which a protection tape is applied on the front surface of the semiconductor wafer shown in FIG. 1;

FIG. 3A and FIG. 3B are explanatory diagrams showing a masking step in the method for forming an electrode of a semiconductor device in accordance with the embodiment of the present invention;

FIG. 4 is an explanatory diagram showing an electrode forming step in the method for forming an electrode of a semiconductor device in accordance with the embodiment of the present invention;

FIG. 5 is an enlarged sectional view of the semiconductor wafer for which the electrode forming step shown in FIG. 4 has been carried out;

FIG. 6 is an explanatory diagram showing a mask component separating step in the method for forming an electrode of a semiconductor device in accordance with the embodiment of the present invention; and

FIG. 7 is an explanatory diagram showing a gold collecting step in the method for forming an electrode of a semiconductor device in accordance with the embodiment of the present invention.

### DETAILED DESCRIPTION OF THE PREFERRED EMBODIMENTS

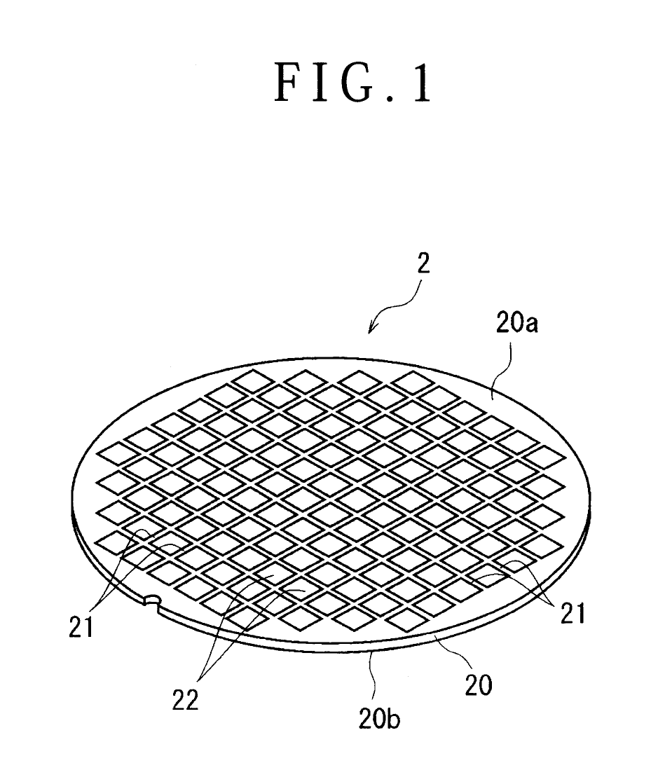

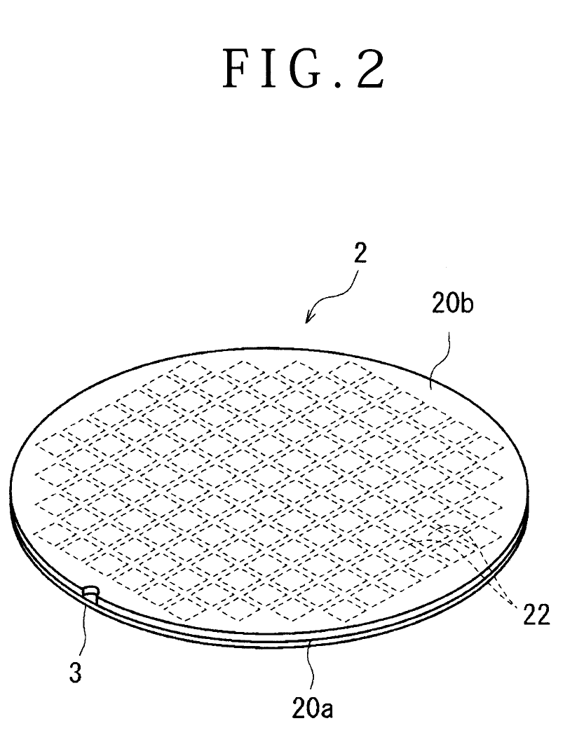

A method for forming electrodes on a back surface of a semiconductor wafer in accordance with an embodiment of the present invention will be described in detail below with reference to the accompanying drawings. FIG. 1 is a perspective view of a semiconductor wafer to be processed by the method for forming electrodes on a back surface of a semiconductor wafer in accordance with the embodiment of the present invention. A semiconductor wafer 2 shown in FIG. 1 is obtained as follows for example. Specifically, plural rectangular areas defined by plural streets 21 formed in a lattice manner are formed on a front surface 20a of a semiconductor substrate 20 that has a thickness of 100 μm and is composed of silicon. Furthermore, devices 22 such as insulated gate bipolar transistors or the like are formed in these plural rectangular areas. On the front surface 20a of the semiconductor substrate 20 as part of this semiconductor wafer 2, a protection tape 3 is applied as shown in FIG. 2 in order to protect the devices 22 (protection tape applying step).

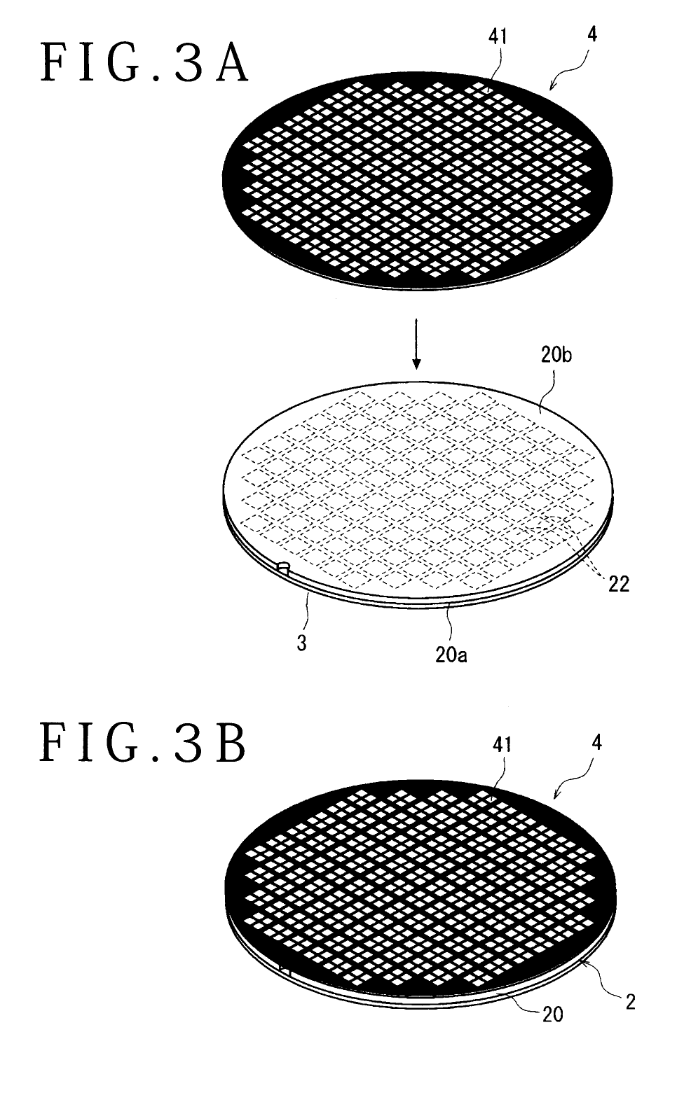

Subsequently, as shown in FIGS. 3A and 3B, a masking step of applying a mask component 4 on a back surface 20b of the semiconductor substrate 20 is carried out. The mask component 4 has apertures 41 formed in the areas corresponding to the electrode areas of the devices 22, on the back surface 20b of the semiconductor substrate 20 as part of the semiconductor wafer 2. The mask component 4 is formed of an appropriate synthetic resin sheet. The plural apertures 41 are formed by punching through the areas corresponding to the electrode areas of the devices 22 formed on the front surface 20a of the semiconductor substrate 20. An adhesive is applied on the back surface of the thus formed mask component 4, and the mask component 4 is bonded to the back surface 20b of the semiconductor substrate 20 by this adhesive. In the masking step, the apertures may be formed by covering the back surface 20b of the semiconductor substrate 20 with a photoresist film and exposing the electrode areas through a patterned mark.

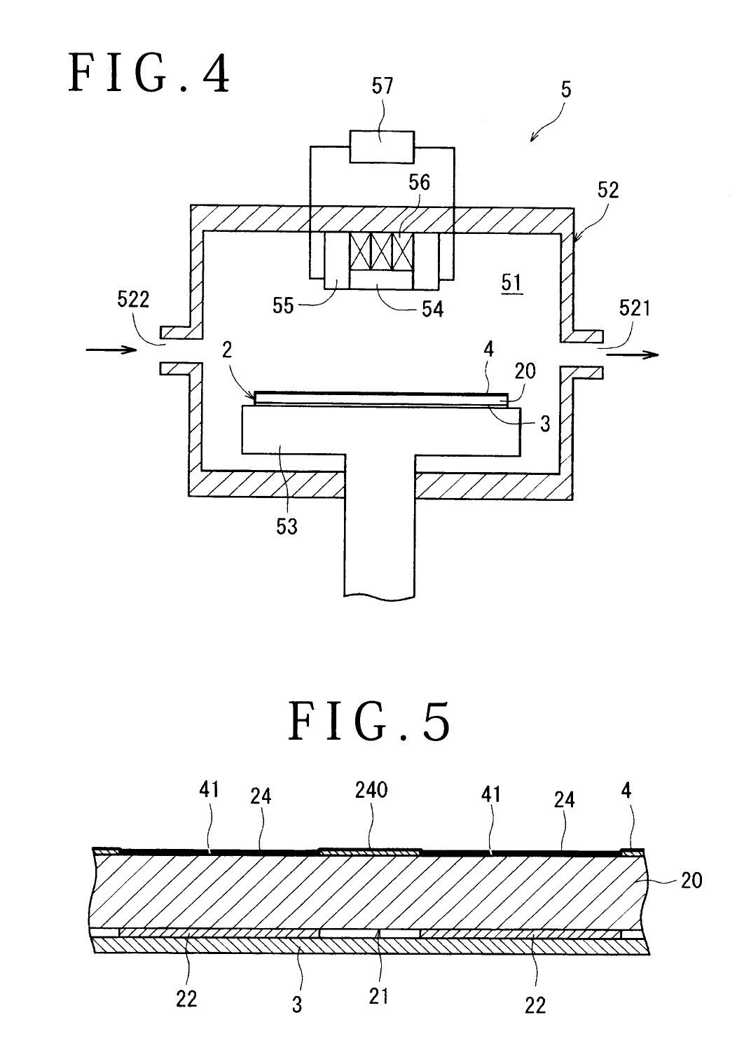

The above-described masking step is followed by an electrode forming step in which gold is deposited by sputtering on the back surface 20b of the semiconductor substrate 20 as part of the semiconductor wafer 2 and electrodes are formed on the back surface 20b of the semiconductor substrate 20 corresponding to electrode areas of the devices 22. This electrode forming step is carried out by using sputtering apparatus 5 shown in FIG. 4. The sputtering apparatus 5 shown in FIG. 4 includes a housing 52 offering a sputtering chamber 51 and an electrostatic-attraction-type holding table 53 that is provided in the sputtering chamber 51 of the housing 52 and serves as an anode on which a processing subject is held. The sputtering apparatus 5 further includes a cathode 55 that is so provided as to face the holding table 53 and to which a target 54 composed of gold (Au) to be deposited is attached, excitation means 56 for exciting the target 54, and a high-frequency power supply 57 for applying a high-frequency voltage to the cathode 55. For the housing 52, a pressure reduction port 521 that allows the sputtering chamber 51 to communicate with pressure reduction means (not shown) and an introduction port 522 that allows the sputtering chamber 51 to communicate with sputtering gas supply means (not shown) are provided.

To carry out the above-described electrode forming step by using the sputtering apparatus 5 with the above-described structure, the semiconductor wafer 2 for which the above-described masking step has been carried out is disposed on the holding table 53 and held by electrostatic attraction in such a way that the protection tape 3 applied on the front surface 20a of the semiconductor substrate 20 as part of the semiconductor wafer 2 faces the holding table 53. Therefore, the mask component 4 applied on the back surface 20b of the semiconductor substrate 20 as part of the semiconductor wafer 2 held on the holding table 53 by electrostatic attraction is on the upper side. Subsequently, the excitation means 56 is operated to excite the target 54, and a high-frequency voltage with a frequency of e.g. 40 kHz is applied from the high-frequency power supply 57 to the cathode 55. Furthermore, the pressure reduction means (not shown) is operated to reduce the pressure in the sputtering chamber 51 to about 10⁻² Pa to 10⁻⁴ Pa. In addition, the sputtering gas supply means (not shown) is operated to introduce an argon gas into the sputtering chamber 51 to thereby generate plasma. Thus, the argon gas in the plasma collides with the target 54, which is attached to the cathode 55 and composed of gold. Due to gold particles scattered by this collision, a gold layer is deposited on the mask component 4 and disposed on the back surface 20b of the semiconductor substrate 20 as part of the semiconductor wafer 2 through the plural apertures 41 formed in the mask component 4. As a result, as shown in FIG. 5, electrodes 24 formed of the gold (Au) layer are formed in the electrode areas of the devices 22, on the back surface 20b of the semiconductor substrate 20. In addition, a gold (Au) layer 240 is also deposited on the surface of the mask component 4.

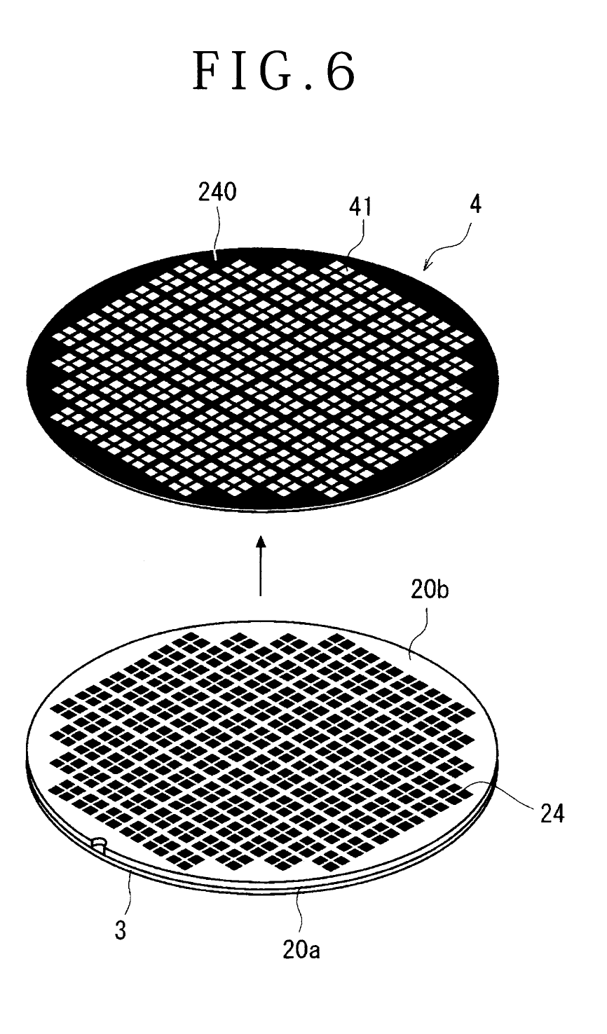

The above-described electrode forming step is followed by a mask component separating step of separating the mask component 4 applied on the back surface 20b of the semiconductor substrate 20 as part of the semiconductor wafer 2 as shown in FIG. 6. As a result, the plural electrodes 24 composed of gold (Au) are formed in the electrode areas of the devices 22, on the back surface 20b of the semiconductor substrate 20 as part of the semiconductor wafer 2. Furthermore, the gold (Au) layer 240 is deposited on the surface of the mask component 4 separated from the back surface 20b of the semiconductor substrate 20.

Subsequently, in a dividing step, the semiconductor wafer 2 for which the plural electrodes 24 composed of gold (Au) have been formed in the electrode areas of the plural devices 22, on the back surface 20b of the semiconductor substrate 20 is cut along the streets 22 by cutting apparatus or the like and divided into the individual devices 22 each having the electrode 24 on the back surface thereof.

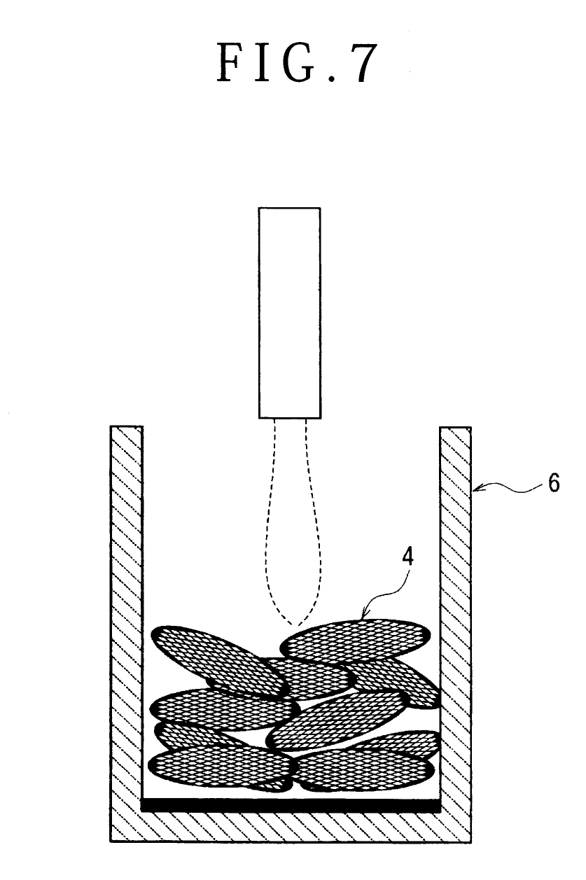

On the other hand, the gold (Au) layer 240 is deposited on the surface of the mask component 4 as described above. This gold (Au) is collected because disposal thereof is uneconomical. As a method for colleting the gold (Au), for example, as shown in FIG. 7, the mask components 4 on which the gold (Au) layer 240 has been deposited are put in an incinerator 6 and the mask components 4 composed of synthetic resin are incinerated to thereby collect the gold (Au) deposited on the surfaces of the mask components 4 (gold collecting step).

As described above, in the above-described embodiment, the mask component 4 having the apertures 41 formed in the areas corresponding to the electrode areas of the devices 22, on the back surface 20b of the semiconductor substrate 20, is applied on the back surface 20b of the semiconductor substrate 20. In this state, gold (Au) is deposited by sputtering on the back surface 20b of the semiconductor substrate 20 as part of the semiconductor wafer 2 to thereby form electrodes in the electrode areas of the devices 22, on the back surface 20b of the semiconductor substrate 20. Therefore, the minimum necessary amount of gold (Au) is deposited on the back surface 20b of the semiconductor substrate 20. Furthermore, the gold (Au) layer 240 deposited on the surface of the mask component 4 by the sputtering is collected, and thus the gold (Au), which is expensive, can be reused.

The present invention is not limited to the details of the above described preferred embodiments. The scope of the invention is defined by the appended claims and all changes and modifications as fall within the equivalence of the scope of the claims are therefore to be embraced by the invention.

What is claimed is:

1. A method for forming an electrode on a back surface of a semiconductor substrate of a semiconductor wafer having a plurality of devices formed in areas defined by a plurality of streets formed in a lattice manner on a front surface of the semiconductor substrate, the method comprising:
a masking step of applying a mask having a plurality of apertures formed in areas corresponding to each electrode area of the each device, on the back surface of the semiconductor substrate;
an electrode forming step of depositing, by sputtering, gold on the back surface of the semiconductor substrate for which the masking step has been carried out to thereby form the electrode in the electrode area of the each device, on the back surface of the semiconductor substrate;
a mask separating step of separating the mask applied on the back surface of the semiconductor substrate for which the electrode forming step has been carried out; and
a gold collecting step of collecting gold deposited on the mask separated in the mask separating step.
